(19) United States
(12) Patent Application Publication
(10) Pub. No.: US 2005/0140005 A1
(43) Pub. Date: Jun. 30, 2005

(54) Chip package structure

(75) Inventors: Ya-Ling Huang, Kaohsiung City (TW); Tzu-Bin Lin, Kaohsiung City (TW); Hung-Ta Hsu, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/023,354

(22) Filed: Dec. 29, 2004

(30) Foreign Application Priority Data
Dec. 31, 2003 (TW) 92137814

(51) Int. Cl. H01L 21/44; H01L 23/52

(52) U.S. Cl. 257/737; 438/613; 257/738

(57) ABSTRACT

A chip package structure is disclosed. The chip package structure includes an inner molding compound with a low modulus covering the chip and an outer molding compound covering the inner molding compound. The outer molding compound has a modulus larger than then modulus of the inner molding compound.

### BACKGROUND OF THE INVENTION

1. Field of the Invention

The present invention generally relates to a chip package structure, and more particularly to solve the problem for a chip package structure with a stress loading in the low dielectric constant fabrication process.

2. Description of the Prior Art

In a chip package structure, the molding compound such as QFP (quad flat package), or BGA (ball grid array) is used as a package material for preventing the effect of the chip from the outside environment influence and the force impact. The molding material has the strength, hardness, and the physical properties especially for a coefficient of thermal expansion (CTE) to protect the chip to be electrical coupled with other devices, and would not be affected by outside environment. However, the properties of the molding material sometime would be damaged the chip, especially the stress problem exists in the molding material and the chip. When the heat sink is placed on the chip to increase the heat dissipation, because of the chip operating is under the thermal cycle, such as raised, maintained, or lowered the temperature, and the coefficient of thermal expansion is different between the molding material, heat sink, and the chip, so that the stress variation is an important issue between the molding material, heat sink, and the chip in the packaging process and package structure.

According to abovementioned, the stress problem between the molding material and the chip is more critical when the low dielectric constant (low k) material and the thin wafer is utilized, and the distance between the line width and the device is to be diminished for the performance requirement. Nevertheless, the heat sink would be produced the stress problem, thus, the peeling between the chip substrate and the wiring would be generated during the low dielectric (low K) process. The stress problem would be raised when the chip is operating. The coefficient of thermal expansion is large when the material of the heat sink is metal, and the heat sink would be affected after the molding material is filled into the mold to cover the chip, so as to the molding compound is to be split around the chip.

### SUMMARY OF THE INVENTION

It is an object of this invention to solve the stress problem which is produced by the heat sink to make the chip and wiring peeling in the low dielectric (low k) fabrication.

It is another object of this invention to solve the molding compound around the chip that is to be split after molding process.

According to abovementioned objects, the present invention provides an inner molding compound used to cover the chip and an outer molding compound used to cover the inner molding compound to release the stress, so that can be prevented the chip from the outside environment influence and force impact. The modulus, hardness, and strength for the outer molding compound are larger than the ones of the inner molding compound.

Contrast to the prior art and the present invention, the present invention utilizes the molding compound with low modulus to cover the chip, and an outer molding compound is covered the inner molding compound, such that the peeling resulting from the stress between the chip and wires is reduced. Moreover, the present invention also solve the split of the molding compound formed around the chip after the molding process.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic representation of showing a plastic ball grid array (PBGA) package structure in accordance with the first embodiment of the present invention disclosed herein;

FIG. 2 is a schematic representation of showing a quad flat package (QFP) structure in accordance with the second embodiment of the present invention disclosed herein;

FIG. 3 is a schematic representation of showing a stacked ball grid array (stacked BGA) package structure in accordance with the third embodiment of the present invention disclosed herein;

FIG. 4 is a schematic representation of showing a quad flat package non-leaded package structure in accordance with the fourth embodiment of the present invention disclosed herein;

FIG. 5 is a schematic representation of showing a cavity down ball grid array package structure in accordance with the fifth embodiment of the present invention disclosed herein;

FIG. 6 is a schematic representation of showing a bump chip carrier (BCC) package structure in accordance with the sixth embodiment of the present invention disclosed herein;

FIG. 7 is a schematic representation of showing a flip chip ball grid array (FCBGA) package structure in accordance with the seventh embodiment of the present invention disclosed herein; and

FIG. 8 is a schematic representation of showing a flip chip quad flat non-leaded (FCQFN) package structure in accordance with the eighth embodiment of the present invention disclosed herein.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

As shown in FIG. 1, represents a first embodiment of a chip package structure of the present invention. FIG. 1 shows a plastic ball grid array (PBGA) package structure. The PBGA package structure utilizes a die attach epoxy or silver glue to fix the chip 106 on the board 102. The chip 106 is electrically coupled the board 102 with the wires 114 by using wire bonding, in which the board 102 has a plurality of solder balls to electrically couple with the printed circuit board (PCB). The board 102 includes a substrate. The chip 106 includes a first chip that is produced by a low dielectric (low k) fabrication process. The wires 114 can be Al-wires or Au-wires.

Then, an inner molding compound is filed into a mold to form an inner molding compound 112 to cover the chip 106 and the wires 114 as shown in FIG. 1. In order to release the stress, the inner molding compound 112 is soft and has enough elastic modulus, in which the modulus of the inner molding compound 112 is between 500 Mpa and 16000 Mpa. The inner molding compound 112 is an elastic material that is used as a buffer layer to release the stress, in which the material of the inner molding compound 112 is ABLETHERM 3185 (RP-507-30) from Rancho Dominguez. Next, an outer molding compound covers the inner molding compound 112 to form an outer molding compound 108 as shown in FIG. 1. The outer molding compound 108 has enough strength, hardness, and the modulus, in which the modulus is between 35000 Mpa and 16000 Mpa, and the material of the outer molding compound 108 is epoxy. The material request for the inner/outer molding compound (108/112) is that the modulus of the outer molding compound 108 is larger than the modulus of the inner molding compound 112.

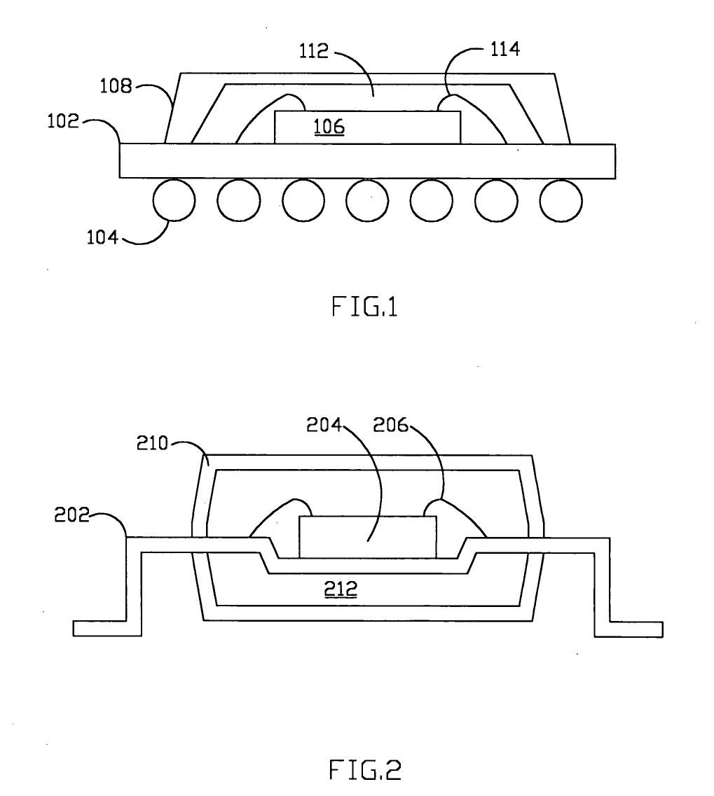

As shown in FIG. 2, represents a second embodiment of the chip package structure of the present invention. FIG. 2 shows a quad flat package (QFP) structure. The chip 204 is fixed on the board 202. The board 202 includes a leadframe (not shown). The QFP structure utilizes the die attach epoxy or silver glue to fix the chip 204 on the die attached pad of the leadframe. Then, the input/output pads of the chip 204 are electrically coupled with the pins of the leadframe through the wires 206 by the wire bonding. The chip 204 includes a first chip that is produced by the low k fabrication process. The wires 206 can be Al-wires or Au-wires. Then, performing a molding process, the board 202 and the chip 204 are placed into the mold. Then, the inner molding compound 212 is filled into the mold to form an inner molding compound 212 to cover the chip 204 and the die attached pad of the board 202 as shown in FIG. 2. In order to release the stress, the inner molding compound 212 is soft and has enough elastic modulus, in which the modulus of the inner molding compound 212 is between 500 Mpa and 16000 Mpa. The inner molding compound 212 is an elastic material which is used as a buffer layer to release the stress, in which the material of the inner molding compound 212 is ABLETHERM 3185 (RP-507-30) from Rancho Dominguez. Then, an outer molding compound is covered on the inner molding compound 212 to form an outer molding compound 210 as shown in FIG. 2. The outer molding compound 210 has enough strength, hardness, and the modulus, in which the modulus is between 35000 Mpa and 16000 Mpa, and the material of the outer molding compound 210 is epoxy. The material request for the inner/outer molding compound (212/210) is that the modulus of the outer molding compound 210 is larger than the modulus of the inner molding compound 212.

As shown in FIG. 3, represents a third embodiment of the chip package structure of the present invention. FIG. 3 shows a stacked ball grid array (stacked BGA) package structure. The stacked BGA package structure utilizes the die attach epoxy or sliver glue to fix the chip 306 on the board 302, and then the chip 308 is fixed on the chip 306. The chips 306 and 308 are further electrically coupled with the board 302 through the wires 310a and wires 310b respectively by the wire boding. The board 302 has a plurality of solder balls 304 to electrically couple with a printed circuit board (PCB). The board 302 includes a substrate. The chips 306 and 308 include the chips that are produced by a low k fabrication process. The wires 310a and 310b can be Al-wires or Au-wires. Next, performing a molding process, the board 302 and the chips 306, 308 are placed into the mold. Then, an inner molding compound is filled into the mold to form the inner molding compound 312 to cover the chips 306 and 308 as shown in FIG. 3. In order to release the stress, the inner molding compound 312 is soft and has enough elastic modulus, in which the modulus of the inner molding compound 312 is between 500 Mpa and 16000 Mpa. The inner molding compound 312 is an elastic material that is used as a buffer layer to release the stress, in which the material of the inner molding compound 312 is ABLETHERM 3185 (RP-507-30) from Rancho Dominguez. Then, an outer molding compound is covered the inner molding compound 312 to form an outer molding compound 316 as shown in FIG. 3. The outer molding compound 316 has enough strength, hardness, and the modulus, in which the modulus is between 35000 Mpa and 16000 Mpa, and the material of the outer molding compound 316 is epoxy. The material request for the inner/outer molding compound (312/316) is that the modulus of the outer molding compound 316 is larger than the modulus of the inner molding compound 312.

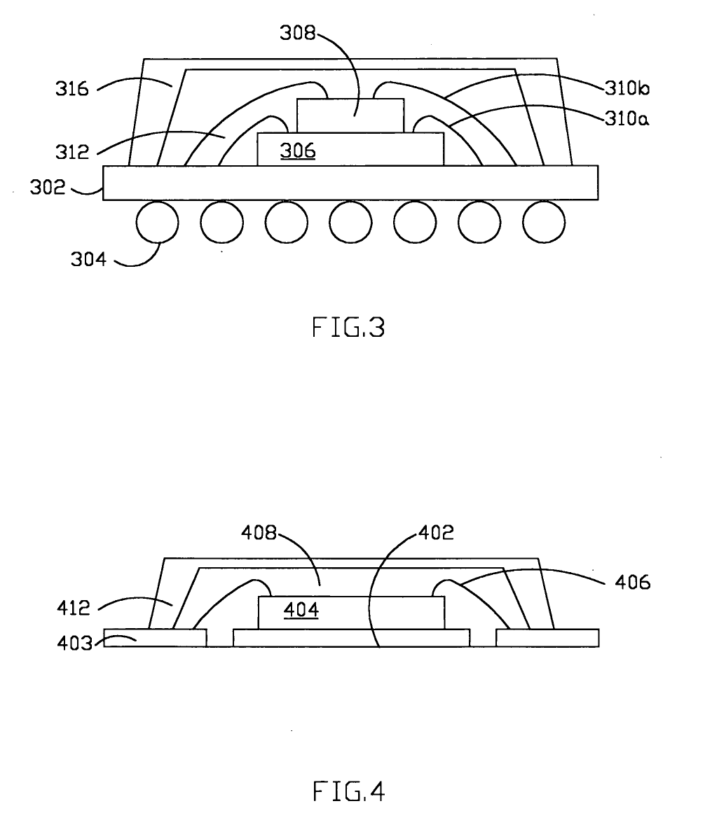

As shown in FIG. 4, represents a fourth embodiment of the chip package structure of the present invention. FIG. 4 shows a quad flat package non-leaded package structure. The quad flat package non-leaded package structure utilizes the die attach epoxy or the sliver glue to fix the chip 404 on the die pad 402. The input/output pads of the chip 404 are electrically coupled the pins 403 of the board (not shown) with the wires 406 by the wire bonding. The board includes a leadframe. The chip 404 includes a first chip that is produced by a low k fabrication process. The wires 406 can be Al-wires or Au-wires. Then, performing a molding process, the die pad 402 and the chip 404 are placed into the mold. Then, an inner molding compound is filled into the mold to form an inner molding compound 408 to cover the chip 404 as shown in FIG. 4. In order to release the stress, the inner molding compound 408 is soft and has enough elastic modulus, in which the modulus of the inner molding compound 408 is between 500 Mpa and 16000 Mpa. The inner molding compound 408 is an elastic material that is used as a buffer layer to release the stress, in which the material of the inner molding compound 408 is ABLETHERM 3185 (RP-507-30) from Rancho Dominguez. Then, an outer molding compound is covered the inner molding compound 408 to form the outer molding compound 412 as shown in FIG. 4. The outer molding compound 412 has enough strength, hardness, and the modulus, in which the modulus is between 35000 Mpa and 16000 Mpa, in which the material of the outer molding compound 412 is epoxy. The material request for the inner/outer molding compound (408/412) is that the modulus of the outer molding compound 412 is larger than the modulus of the inner molding compound 408.

As shown in FIG. 5, represents a fifth embodiment of the chip package structure of the present invention. FIG. 5 shows a cavity down ball grid array package structure. In this package structure, the substrate 502 and the chip 504 are fixed on the heat sink 506. The substrate 502 and the heat sink 506 construct a cavity to contain the chip 504. Then, the input/output pads of the chip 504 are electrically coupled the substrate 502 with the wires 508 by the wire bonding. The substrate 502 has solder balls 516 to electrically couple with the printed circuit board (PCB). The substrate 502 and the heat sink 506 can construct a board. The structure of FIG. 5 also includes dams 518 and 520. The height of the dam 520 is higher than the height of the dam 518, and the height of the dam 518 is higher than the wires 508. The dams 518 and 520 can prevent the molding compound from the overflow when the molding compound is filled. The chip 504 includes a first chip that is produced by the low k fabrication process. The wires 508 can be Al-wires or Au-wires. Then, performing a molding process, an inner molding compound is covered the chip 504 and the wires 508 to form the inner molding compound 510 as shown in FIG. 5. In order to release the stress, the inner molding compound 510 is soft and has enough elastic modulus, in which the modulus of the inner molding compound 510 is between 500 Mpa and 16000 Mpa. The material of the inner molding compound 510 is an elastic material that is used as a buffer layer to release the stress, in which the material of the inner molding compound 510 is ABLETHERM 3185 (RP-507-30) from Rancho Dominguez. Then, an outer molding compound is covered the inner molding compound 510 to form the outer molding compound 514 as shown in FIG. 5. The outer molding compound 514 has enough strength, hardness, and the modulus, in which the modulus is between 35000 Mpa and 16000 Mpa, and the material of the outer molding compound 514 is epoxy. The material request for the inner/outer molding compound (510/514) is that the modulus of the outer molding compound 514 is larger than the modulus of the inner molding compound 510.

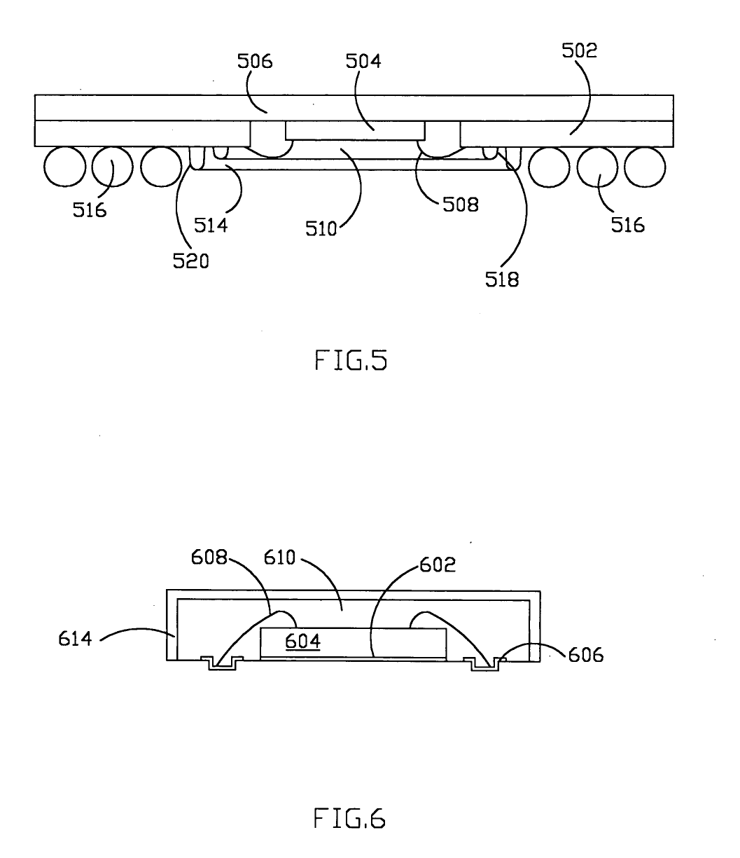

As shown in FIG. 6, represents a sixth embodiment of the chip package structure of the present invention. FIG. 6 shows a bump chip carrier (BCC) package structure. The BCC package structure utilizes the glue layer 602 to fix the chip 604 on the metal plate (not shown). The chip 604 is electrically coupled the metal electrodes 606 of the metal plate with the wires 608 by the wire bonding. The glue layer 602 includes a die attach epoxy or the silver glue. The chip 604 includes a first chip that is produced by a low k fabrication process. The wires 608 can be Al-wires or Au-wires. Then, performing a molding process, the metal plate and the chip 604 are placed into the mold. Then, an inner molding compound is filled into the mold to form the inner molding compound 6.10 to cover the chip 604 as shown in FIG. 6. In order to release the stress, the inner molding compound 610 is soft and has enough elastic modulus, in which the modulus of the inner molding compound 610 is between 500 Mpa and 16000 Mpa. The material of the inner molding compound 610 is an elastic material, which is used as a buffer layer to release the stress, in which the material of the inner molding compound 610 is ABLETHERM 3185 (RP-507-30) from Rancho Dominguez. Next, an outer molding compound is covered the inner molding compound 610 to form the outer molding compound 614 as shown in FIG. 6. Thereafter, performing an etching process to remove the metal plate to remain the metal electrodes 606, or remain both the metal electrodes 606 and the exposed die pad (not shown). Then, the metal electrode 606 or both the metal electrode 606 and the exposed die pad (not shown) is electrically coupled with the outer circuit such as printed circuit board (PCB) to form a bump chip carrier as shown in FIG. 6. The outer molding compound 614 has enough strength, hardness, and the modulus, in which the modulus is between 35000 Mpa and 16000 Mpa, and the material of the outer molding compound 614 is epoxy. The material request for the inner/outer molding compound (610/614) is that the modulus of the outer molding compound 614 is larger than the modulus of the inner molding compound 610.

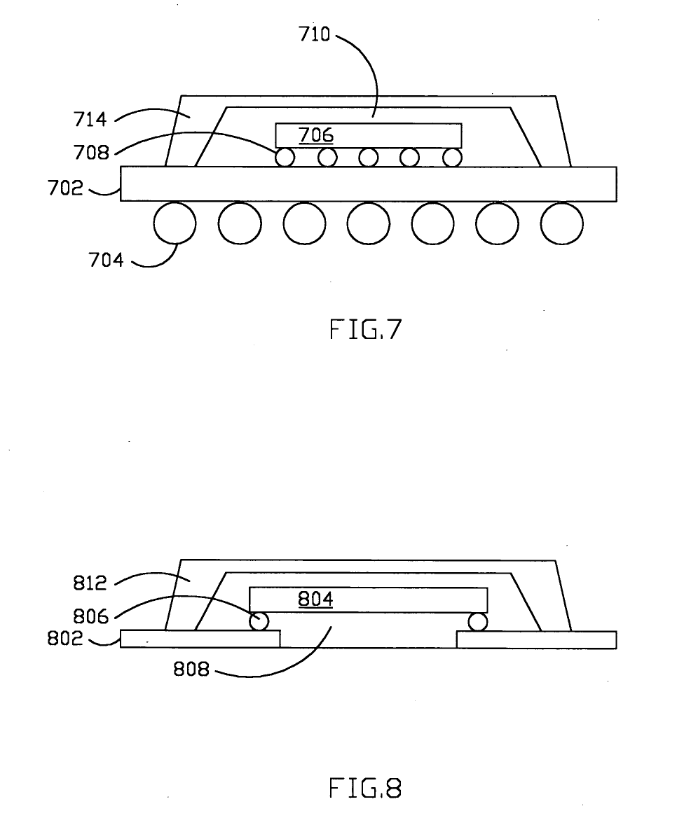

As shown in FIG. 7, represents a seventh embodiment of the chip package structure of the present invention. FIG. 7 shows a flip chip ball grid array (FCBGA) package structure. The chip 706 has multitudes of solder bumps 708 on an active surface downward to electrically couple with the metal pad (for example, Cu pad) of the board 702 through the solder bumps 708. The board 702 includes a substrate. The chip 706 includes a first chip that is produced by a low k fabrication process. The material of solder bumps is not only Sn-Pb alloy but also lead-free that could be utilized in the packaging process. The board 702 has a plurality of solder balls 704 to electrically couple with the printed circuit board (PCB). Then, performing a molding process, the inner molding compound is filled into the mold to form an inner molding compound 710 to cover the chip 706 as shown in FIG. 7. In order to release the stress, the inner molding compound 710 is soft and has enough elastic modulus, in which the modulus of the inner molding compound 710 is between 500 Mpa and 16000 Mpa. The material of the inner molding compound 710 is an elastic material that is used as a buffer layer to release the stress, in which the material of the inner molding compound 710 is ABLETHERM 3185 (RP-507-30) from Rancho Dominguez. Then, an outer molding compound is covered the inner molding compound 710 to form the outer molding compound 714 as shown in FIG. 7. The outer molding compound 714 has enough strength, hardness, and the modulus, in which the modulus of the outer molding compound 714 is between 35000 Mpa and 16000 Mpa, and the material of the outer molding compound 714 is epoxy. The material request for the inner/outer molding compound (710/714) is that the modulus of the outer molding compound 714 is larger than the modulus of the inner molding compound 710.

As shown in FIG. 8, represents an eighth embodiment of the chip package structure of the present invention. FIG. 8 shows a flip chip quad flat non-leaded (FCQFN) package structure. The active surface of the chip 804 is downward to electrically couple the pins 802 of the board with the solder bumps 806. The chip 804 includes a first chip that is produced by a low k fabrication process. Then, performing a molding process, an inner molding compound is filled into the mold to form the inner molding compound 808 to cover the chip 804 as shown in FIG. 8. The inner molding compound 808 is full of the space adjacent the pins 802. In order to release the stress, the inner molding compound 808 is soft and has enough elastic modulus, in which the modulus of the inner molding compound 808 is between 500 Mpa and 16000 Mpa. The material of the inner molding compound 808 is elastic material, which can use as a buffer layer to release the stress, in which the material of the inner molding compound 808 is ABLETHERM 3185 (RP-507-30) from Rancho Dominguez. Then, an outer molding compound is covered the inner molding compound 808 to form the outer molding compound 812 as shown in FIG. 8. The outer molding compound 812 has enough strength, hardness, and the modulus, in which the modulus of the outer molding compound 812 is between 35000 Mpa and 16000 Mpa, in which the material of the outer molding compound 812 is epoxy. The material request for the inner/outer molding compound (808/812) is that the modulus of the outer molding compound 812 is larger than the modulus of the inner molding compound 808.

Although specific embodiments have been illustrated and described, it will be obvious to those skilled in the art that various modifications may be made without departing from what is intended to limit solely by the appended claims.

1. A chip package structure, said chip package structure comprising:
a board;
a first chip on said board, wherein said first chip has a plurality of first conductors electrically coupling with said board and said first chip;
an inner molding compound covering said first chip and said first conductors; and
an outer molding covering said inner molding compound, wherein the modulus of said outer molding compound is higher than the modulus of said inner molding compound.

2. The chip package structure according to claim 1, wherein said board has a plurality of solder balls constructing a ball grid array package structure are on a surface of said board that is opposite to a surface of said first chip.

3. The chip package structure according to claim 1, wherein the material of said inner molding compound is ABLETHERM 3185 (RP-507-30).

4. The chip package structure according to claim 1, further comprising a second chip on said first chip, wherein said second chip has a plurality of second conductors electrically coupling with said board and said second chip for constructing a stacked ball grid array package structure.

5. The chip package structure according to claim 1, wherein the material of said outer molding compound is epoxy.

6. The chip package structure according to claim 1, wherein the modulus of said inner molding compound is between 500 Mpa and 16000 Mpa.

7. The chip package structure according to claim 1, wherein the modulus of said outer molding compound is between 35000 Mpa and 16000 Mpa.

8. The chip package structure according to claim 1, wherein said first chip is produced by a low dielectric (low k) fabrication process.

9. The chip package structure according to claim 1, wherein said board is one of a circuit substrate and a leadframe.

10. The chip package structure according to claim 1, wherein said board is a leadframe, and said chip package structure is a quad flat package structure.

11. The chip package structure according to claim 1, wherein said board is a leadframe, and said chip package structure is a quad flat non-leaded package structure.

12. The chip package structure according to claim 1, wherein said board comprises a heat sink and a substrate adhered on said heat sink to form a cavity for containing said first chip, and said chip package structure further comprised a plurality of solder balls on a surface of said substrate for structurally and electrically coupling with a printed circuit board.

13. The chip package structure according to claim 1, wherein said first conductor comprises a plurality of solder bumps for mechanically and electrically coupling with said board by using flip chip.

14. The chip package structure according to claim 1, wherein said first conductors comprise a plurality of wires.

15. The chip package structure according to claim 1, wherein said board is a leadframe, and said first chip is mechanically and electrically coupled said chip and said leadframe with a plurality of solder bumps to form a flip chip quad flat non-leaded packaged structure by a flip chip process.

16. The chip package structure according to claim 12, wherein said substrate comprises a plurality of first dams and a plurality of second dams, and the height of said first dam is higher than the height of said second dam, and said first dam is adjacent to said chip.

17. A chip package structure, said chip package structure comprising:
a chip electrically coupling with a plurality of metal electrodes through a plurality of wires;
an inner molding compound covering said chip, said wires, and a first surface of said metal electrodes and having a portion exposing a second surface of metal electrode, and said second surface opposite to said surface and configured for electrically coupling with a surface of said inner molding compound; and
an outer molding compound covering said inner molding compound and having a portion exposing a second surface of said metal electrode, and said second surface electrically coupling with an outer circuit, wherein the modulus of said outer molding compound is larger than the modulus of said inner molding compound.

18. The chip package structure according to claim 17, wherein the material of said inner molding compound is ABLETHERM 3185 (RP-507-30).

19. The chip package structure according to claim 17, wherein the material of said outer molding compound is epoxy.

20. The chip package structure according to claim 17, wherein the modulus of said inner molding compound is between 500 Mpa and 16000 Mpa.

21. The chip package structure according to claim 17, wherein the modulus of said outer molding compound is between 35000 Mpa and 16000 Mpa.

22. The chip package structure according to claim 17, wherein said first chip is produced by a low k fabrication process.

23. The chip package structure according to claim 17, further comprising a die attached pad located on said surface of said inner molding compound, and said die attached pad coupled with said chip through a glue layer.
